(19) United States
(12) Patent Application Publication
(10) Pub. No.: US 2007/0114578 A1
(43) Pub. Date: May 24, 2007

(54) LAYOUT STRUCTURE OF BALL GRID ARRAY

(75) Inventor: Ya-Ling Huang, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,542

(22) Filed: Aug. 18, 2006

(30) Foreign Application Priority Data
Nov. 24, 2005 (CN) 200510101741.X

(51) Int. Cl. H01L 29/80

(52) U.S. Cl. 257/276

(57) ABSTRACT

A layout structure of ball grid array is provided. The layout structure includes: a substrate having a margin area; a plurality of solder ball pads laid on the substrate; a plurality of interconnection vias each electrically coupled to a corresponding one of the plurality of solder ball pads; and at least one of the plurality of interconnection vias arrayed on the margin area so that no interconnection vias are arrayed between one of the plurality of interconnection vias and an edge of the margin area.

### FIELD OF THE INVENTION

The present invention relates to electrical devices, and particularly to a layout structure of a ball grid array.

### DESCRIPTION OF RELATED ART

A ball grid array (BGA) is one particular type of surface mount package on a circuit board. The BGA includes an array of connections on the bottom side of the connector package. In the BGA, pins extending into the circuit board are replaced by small solder balls placed on the bottom side of the connector at each contact location. The circuit board, rather than holes, has an array of solder ball pads matching the solder ball placements on the connector bottom. Connections are made by re-flowing the solder balls to mechanically and electrically engage the connector to the circuit board.

A conventional layout structure for a BGA is described in the following with reference to FIGS. 3-4.

FIG. 3 shows a schematic plan view of a surface layer 100 of a BGA substrate utilizing a conventional layout structure. As shown in FIG. 3, four uniformly aligned quadrants labeled 1-4 are established using the X-axis and Y-axis that intersect at the middle of the substrate and that are orthogonal to each other. The surface layer 100 includes a layout area 120 and a margin area 130. On the layout area 120, each one of the interconnection vias 112 and a corresponding one of the solder ball pads 100 are laid out as pairs along lines that are parallel to each other.

FIG. 4 shows a schematic plan view of an inner layer 200 of a BGA substrate utilizing a conventional layout structure. A metal foil 202 is laid on the inner layer 200. The interconnection vias 112 extend through the surface layer 100 and the inner layer 200. The interconnection vias 112 include an interconnection via 112a needing to be coupled to the metal foil 202, and a majority of interconnection vias 112b isolated from the metal foil 202 by an isolating area 204. If the interconnection via 112a is surrounded by the interconnection vias 112b, as shown in FIG. 4, the interconnection via 112a cannot be coupled to the metal foil 202 directly. A transmission line must be traced to couple the interconnection via 112a with the metal foil 202. However, it is inconvenient to trace beside the dense interconnection vias.

What is needed, therefore, is a layout structure of a ball grid array where the interconnection via needing to be coupled to the metal foil is not isolated from the metal foil.

### SUMMARY OF THE INVENTION

A layout structure of ball grid array is provided. In a preferred embodiment, the layout structure includes: a substrate having a surface layer and an inner layer, the surface layer having a layout area and a margin area, the inner layer having a metal foil and an isolating area; a plurality of solder ball pads arrayed on the layout area of the surface layer; a plurality of interconnection vias isolated from the metal foil by the isolating area, each electrically coupled to a corresponding one of the plurality of the solder ball pads; an inner interconnection via coupled to the metal foil; and at least one of the plurality of interconnection vias laid on the margin area. It is of advantage that with the layout structure the inner interconnection via needing to be coupled to the metal foil is not isolated from the metal foil.

Other advantages and novel features will become more apparent from the following detailed description when taken in conjunction with the accompanying drawings, in which:

### BRIEF DESCRIPTION OF THE DRAWINGS

FIG. 1 is a schematic plan view of a surface layer of a BGA substrate, in accordance with a preferred embodiment of the present invention;

FIG. 2 is a schematic plan view of an inner layer of the BGA substrate of FIG. 1;

FIG. 3 is a schematic plan view of a surface layer of a BGA substrate utilizing a conventional layout structure; and

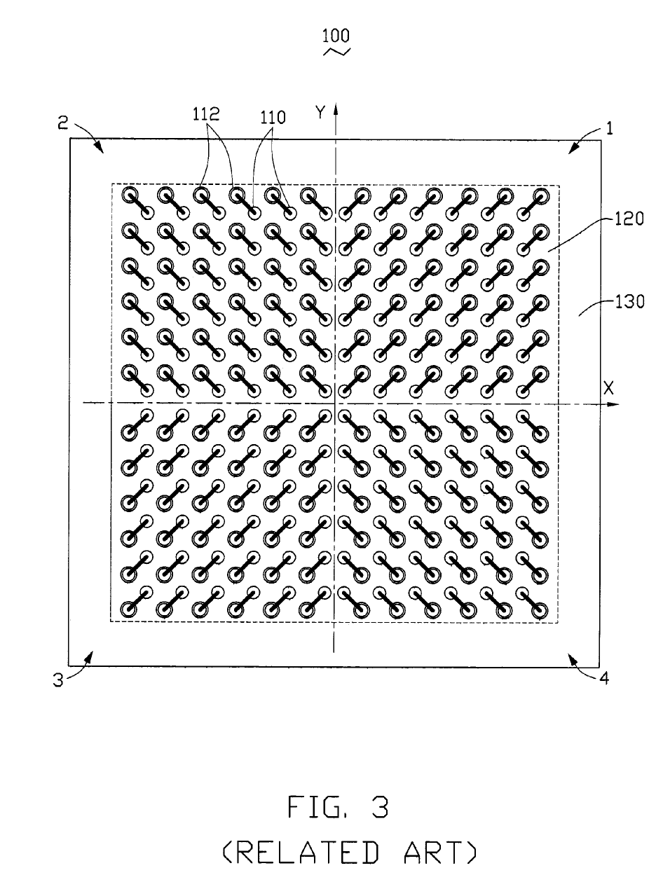

FIG. 4 is a schematic plan view of an inner layer of the BGA substrate of FIG. 3.

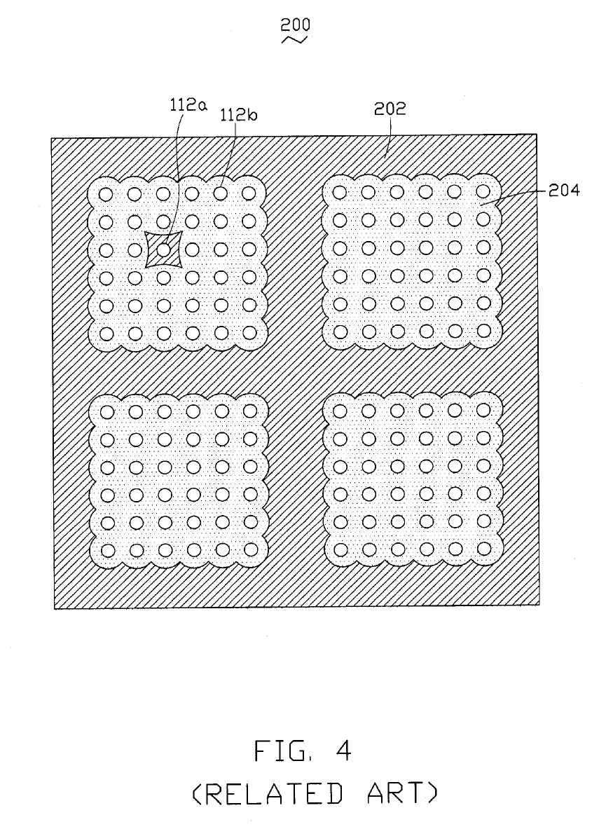

### DETAILED DESCRIPTION OF THE INVENTION

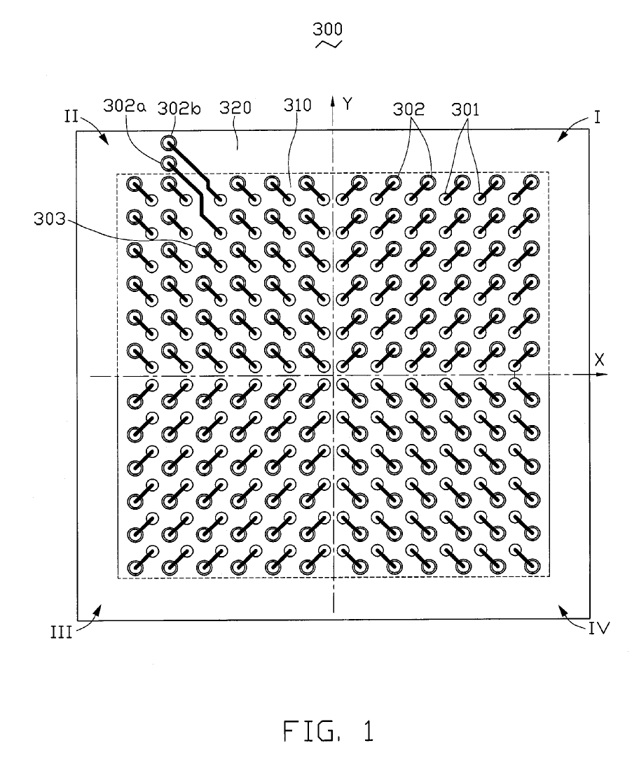

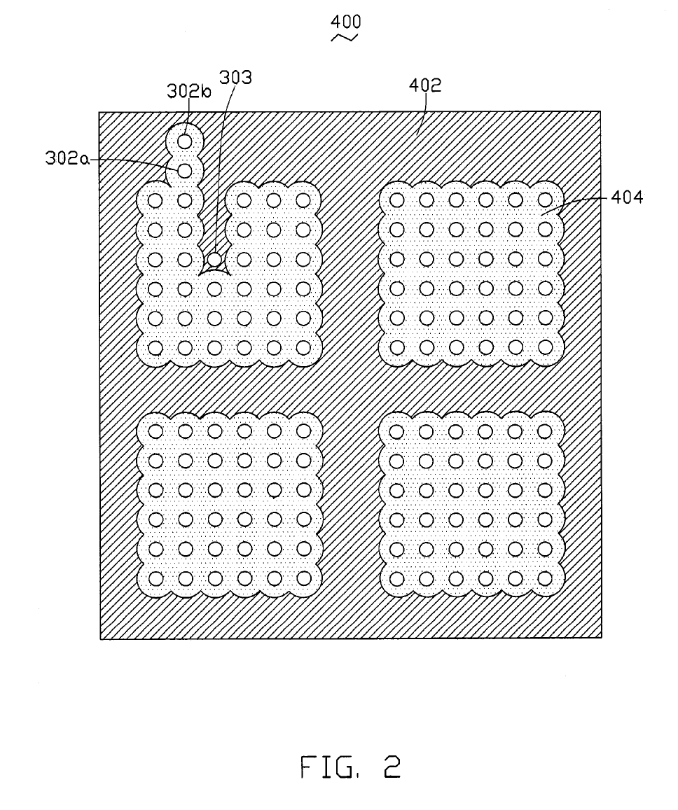

FIG. 1 and FIG. 2 respectively show a schematic plan view of a surface layer 300 and an inner layer 400 of a BGA substrate, in accordance with a preferred embodiment of the present invention. As shown in FIG. 1, four quadrants labeled I-□ are established using an X-axis and a Y-axis that intersect at a middle of the substrate and that are orthogonal to each other. The surface layer 300 includes a layout area 310 and a margin area 320. The inner layer 400 includes a metal foil 402 and an isolating film 404 covered on the metal foil 402. A plurality of solder ball pads 301 is arrayed on the layout area 310 of the surface layer 300. A plurality of interconnection vias 302 and an inner interconnection via 303 (i.e., not located at a periphery of the layout area 310) extend through the surface layer 300 and the inner layer 400. The plurality of interconnection vias 302 is isolated from the metal foil 402 by the isolating film 404, and each is electrically coupled to a corresponding one of the plurality of the solder ball pads 301. The inner interconnection via 303 is located in quadrant II, and electrically coupled to a corresponding one of the plurality of the solder ball pads 301. The plurality of interconnection vias 302 includes a first interconnection via 302a and a second interconnection via 302b located in quadrant II. The first interconnection via 302a and the second interconnection via 302b are laid on the margin area 320, isolated from the metal foil 402 by the isolating film 404, and are each electrically coupled to a corresponding one of the plurality of the solder ball pads 301. No interconnection vias and isolating film 404 are arrayed between the inner interconnection via 303 and an edge of the margin area 320. Thus, the inner interconnection via 303 is electrically coupled to the metal foil 402 directly without transmission line required.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A layout structure of ball grid array comprising:
a substrate comprising a surface layer and an inner layer, the surface layer comprising a layout area and a margin area, the inner layer comprising a metal foil and an isolating area;
a plurality of solder ball pads arrayed on the layout area of the surface layer;
a plurality of interconnection vias isolated from the metal foil by the isolating area, each electrically coupled to a corresponding one of the plurality of the solder ball pads, at least one of the plurality of interconnection vias being arrayed in the margin area; and
an inner interconnection via electrically coupled to the metal foil without use of a transmission line.

2. The layout structure as claimed in claim 1, wherein the plurality of interconnection vias and the inner interconnection via are laid through the surface layer and the inner layer.

3. The layout structure as claimed in claim 1, wherein the substrate is divided into four quadrants by an X-axis and a Y-axis that intersect at a middle of the substrate and that are orthogonal to each other.

4. A layout structure of ball grid array comprising:
a substrate having a margin area;
a plurality of solder ball pads laid on the substrate;
a plurality of interconnection vias each electrically coupled to a corresponding one of the plurality of solder ball pads; and
at least one of the plurality of interconnection vias arrayed on the margin area so that no interconnection vias are arrayed between an inner one of the plurality of interconnection vias and the margin area.

5. The layout structure as claimed in claim 4, wherein the inner one of the plurality of interconnection vias is electrically coupled to a metal foil of the substrate.

6. The layout structure as claimed in claim 4, wherein the substrate comprises a multi-layer substrate.

7. A layout structure of ball grid array comprising:
a substrate comprising a surface layer and an inner layer, the inner layer comprising an electrically conductive area and an electrically isolating area;
a plurality of rows of interconnection vias extending through the surface layer and the inner layer and each electrically coupled to a corresponding one of the plurality of the solder ball pads, the number of the interconnection vias located at one of the rows being different from that located at adjacent row at one side of said one of the rows, the number of the interconnection vias located at said one of the rows being different from that located at another adjacent row at the opposite side of said one of the rows, wherein one of the interconnection vias located at said one of the rows is arrayed at the electrically conductive area at the inner layer.

8. The layout structure as claimed in claim 7, wherein the number of the interconnection vias located at said one of the rows is smaller than that located at said adjacent row at one side of said one of the rows, and the number of the interconnection vias located at said adjacent row at one side of said one of the rows is smaller than that located at said another adjacent row at the opposite side of said one of the rows.

9. The layout structure as claimed in claim 7, wherein the inner layer comprsies a metal foil and an isolating film covered on the metal foil to form the isolating area, the remained area of the metal foil forming the conductive area.
